(19) United States
(12) Patent Application Publication
(10) Pub. No.: US 2023/0411977 A1
(43) Pub. Date: Dec. 21, 2023

(54) BATTERY MANAGEMENT SYSTEM WITH PROTECTION AND EQUALIZATION FUNCTIONS

(71) Applicant: Shenzhen Apeman Innovations Technology Co., Ltd., Shenzhen (CN)

(72) Inventors: Jun HOU, Shenzhen (CN); Lianfu HUANG, Shenzhen (CN)

(73) Assignee: Shenzhen Apeman Innovations Technology Co., Ltd., Shenzhen (CN)

(21) Appl. No.: 17/983,961

(22) Filed: Nov. 9, 2022

(30) Foreign Application Priority Data
Jun. 17, 2022 (CN) 202210688364.8

(51) Int. Cl. H02J 7/00; H01M 10/42; H01M 10/48; H01M 10/44

(52) U.S. Cl. CPC H02J 7/0047; H02J 7/0014; H02J 7/00309; H02J 7/007182; H01M 10/425; H01M 10/486; H01M 10/482; H01M 10/443; H01M 10/441; G01K 1/143

(57) ABSTRACT

The present disclosure provides a battery management system with protection and equalization functions including a dedicated battery management IC, a plurality of sampling circuits and a plurality of execution circuits. A battery protection module and an equalization module are integrated in the dedicated battery management IC. The sampling circuits and the execution circuits are coupled between the dedicated battery management IC and a lithium battery pack, respectively. The sampling circuit collects parameters including voltage, charge-discharge current and battery temperature of the lithium battery pack and inputs them into the dedicated battery management IC for analysis and processing. The dedicated battery management IC outputs control signals to the execution circuits according to a result of the analysis and processing of the parameters, to control the execution circuits to perform battery protection function and voltage equalization function of the lithium battery pack.

### CROSS-REFERENCE TO RELATED DISCLOSURE(S)

This application claims priority under 35 U.S.C. § 119(a) to and the benefit of Chinese Patent Application No. 202210688364.8, filed on Jun. 17, 2022, the entire disclosure of which is hereby incorporated by reference in its entirety.

### TECHNICAL FIELD

The present disclosure relates to the technical field of battery pack management, and more particularly to a battery management system with protection and equalization functions.

### BACKGROUND

Lithium batteries are widely used in mobile portable devices and electric vehicles due to their high energy density, low self-discharge, environmental friendliness, and long cycle life. Due to the active chemical properties of lithium batteries, if overcharge, over-discharge, discharge over-current or overheating occurs during the use of the batteries, it will cause dangers such as battery explosion. Due to small capacity and low load capacity of a battery cell, in order to meet actual needs, people combine the battery cells into a lithium battery pack through certain connection manners. In the lithium battery pack, an important factor affecting the system life is the consistency of the battery cells. Due to the differences in operating temperature, battery capacity, internal resistance and self-discharge among the battery cells, as the number of charge-discharge cycles of the lithium battery pack increases, the differences among the battery cells gradually differentiate, which leads to a decrease in the performance and a shortened life of the lithium battery pack.

In order to solve the problems of overcharge, over-discharge, discharge over-current, overheating and consistency of battery cells during the use of the lithium battery pack, some existing technologies provides an independent battery protection system and an equalization system. That is, the protection function and the equalization function are realized by two different systems respectively. However, due to a large number of components in the two systems, the circuit design is complex and the cost is high.

### SUMMARY

To solve the above-mentioned application defects of existing technologies, the present disclosure provides a battery management system with protection and equalization functions, the technical solution of which is as follows.

A battery management system with protection and equalization functions includes a dedicated battery management IC, a plurality of sampling circuits, and a plurality of execution circuits. The a dedicated battery management IC integrates a battery protection module and an equalization module. The plurality of sampling circuits are coupled between the dedicated battery management IC and a lithium battery pack. The sampling circuits are configured to collect parameters of the lithium battery pack and input the parameters into the dedicated battery management IC for analysis and processing, where the parameters include voltage, charge-discharge current and battery temperature of the lithium battery pack. The dedicated battery management IC is configured to analyze and process the parameters collected by the sampling circuits, and output corresponding control signals according to a result of the analysis and processing of the parameters, where the control signals include a protection signal and an equalization signal. The plurality of execution circuits are coupled between the dedicated battery management IC and the lithium battery pack. The execution circuits are configured to receive the control signals output by the dedicated battery management IC, and perform battery protection function and voltage equalization function of the lithium battery pack. The execution circuits include a protection execution circuit coupled to the battery protection module and an equalization execution circuit coupled to the equalization module. The battery protection module is configured to output the protection signal to the protection execution circuit to control the protection execution circuit to perform the battery protection function of the lithium battery pack. The equalization module is configured to output the equalization signal to the equalization execution circuit to control the equalization execution circuit to perform the voltage equalization function of the lithium battery pack.

In some embodiment, the protection execution circuit includes a charge-discharge control switch coupled in series in a charge-discharge circuit of the lithium battery pack. The battery protection module outputs the protection signal to the charge-discharge control switch to turned on or turned off the charge-discharge control switch, so as to conduct or disconnect the charge-discharge circuit, thereby provide protection for the lithium battery pack during charging and discharging.

In some embodiment, the sampling circuits include a battery temperature sampling circuit, where the battery temperature sampling circuit includes a thermistor closely attached to a surface of the lithium battery pack for collecting the battery temperature of the lithium battery pack, where the resistance value of the thermistor NTC is changes with the change of the battery temperature of the lithium battery pack.

In some embodiment, the dedicated battery management IC further includes a comparator. The battery temperature sampling circuit further includes an adjustable resistor. One terminal of the thermistor is coupled to a non-inverting input terminal of the comparator, and the other end of the thermistor is coupled to an inverting input terminal of the comparator through the adjustable resistor, where the non-inverting input terminal is pulled up to a reference standard voltage through a first resistor, the inverting input terminal is pulled up to the reference standard voltage through a second resistor, and a connection node between the thermistor and the adjustable resistor is grounded. The comparator outputs an output signal according to the voltages at the non-inverting input terminal and the inverting input terminal.

In some embodiment, the battery protection module includes a charge-discharge control unit coupled to the charge-discharge control switch. The dedicated battery management IC further includes a main control unit coupled to the charge-discharge control unit and an output terminal of the comparator, respectively, where the main control unit is configured to determine whether the battery temperature of the lithium battery pack is too high according to the output signal output by the comparator, and then drive, according to a determination result, the charge-discharge control unit to output the protection signal to turn on or turn off the charge-discharge control switch, so as to conduct or disconnect the charge-discharge circuit of the lithium battery pack.

In some embodiment, the lithium battery pack includes a plurality of battery cells. The sampling circuits include a battery voltage sampling circuit configured to collect the voltages of each battery cell of the lithium battery pack. The battery voltage sampling circuit includes a plurality of voltage sampling resistors corresponding to the battery cells of the lithium battery pack one by one, where the voltage sampling resistors also correspond to a plurality of voltage detection pins of the dedicated battery management IC one by one. Where each of the voltage sampling resistors is coupled between a positive electrode of a corresponding battery cell and a corresponding voltage detection pin. The dedicated battery management IC detects the voltage of the positive electrode of each battery cell through a corresponding voltage detection pin and a corresponding voltage sampling resistor.

In some embodiment, the battery voltage sampling circuit further includes a plurality of capacitors corresponding to the voltage detection pins of the dedicated battery management IC one by one, where the capacitors also correspond to the voltage sampling resistors one by one. Each of the capacitors is coupled between a corresponding voltage detection pin and a power ground pin of the dedicated battery management IC. Each of the voltage sampling resistors form a RC filter loop with its corresponding capacitor to filter high-frequency noise on a corresponding battery sampling circuit.

In some embodiment, the lithium battery pack includes a plurality of battery cells coupled in series, where a negative electrode of one of the battery cells is grounded. The sampling circuits include a charge-discharge current sampling circuit configured to collect charge-discharge current of the lithium battery pack, where the charge-discharge current sampling circuit includes a current sampling resistor coupled in series in the charge-discharge circuit of the lithium battery pack, and coupled to a charge-discharge current detection pin of the dedicated battery management IC.

In some embodiment, the current sampling resistor includes a first terminal coupled to the charge-discharge current detection pin, and a second terminal coupled to the negative electrode of the one of the battery cell and grounded. The dedicated battery management IC detects, through the charge-discharge current detection pin, the voltage at the first terminal of the current sampling resistor, and determines a charge-discharge state and a charge-discharge current of the lithium battery pack according to the voltage detected through the charge-discharge current detection pin.

In some embodiment, the charge-discharge control switch includes a first charge-discharge control MOS transistor and a second charge-discharge control MOS transistor coupled in series in the charge-discharge circuit.

In some embodiment, the lithium battery pack includes a plurality of battery cells, the equalization execution circuit includes an equalization MOS array and an equalization transformer, where the equalization MOS array is coupled between the dedicated equalization module and the equalization transformer, the equalization transformer is configured to be coupled to the lithium battery pack. The equalization module outputs the equalization signal to the equalization MOS array to control an on-off state of the equalization MOS array, so as to equalize voltages of the battery cells in the lithium battery pack.

In some embodiment, the equalization module includes a PWM generator that is driven to generate PWM square wave signal and outputs the PWM square wave signal to the MOS array, where the PWM square wave signal is the equalization signal.

In some embodiment, the battery management system includes more than one dedicated battery management ICs that are cascaded, where each cascaded dedicated battery management IC is configured to provide protection and equalization for a preset number of battery cells.

Compared with the existing technologies, the present disclosure has the following technical effects.

The technical solution provided by the present disclosure integrates the battery protection module and the equalization module, which can greatly reduce the circuit components of the protection board and the cost, save the space size of the protection board, and make the battery system lower in cost, smaller in size, simpler in circuit, higher in reliability.

### BRIEF DESCRIPTION OF THE DRAWINGS

In order to illustrate the technical solutions of the embodiments of the present disclosure more clearly, the accompanying drawings required for describing the embodiments of the present disclosure will be briefly introduced below. It is obvious that the accompanying drawings in the following description only illustrate some embodiments of the present disclosure. Those of ordinary skill in the art may also obtain other drawings based on these accompanying drawings without paying any creative efforts.

FIG. 1 is a schematic diagram of functional modules of a battery management system with protection and equalization functions according to the present disclosure.

FIG. 2 is a working schematic diagram of the battery management system with protection and equalization functions according to the present disclosure.

FIG. 3 is a IC cascade working schematic diagram of the battery management system with protection and equalization functions according to the present disclosure.

FIG. 4 is a schematic diagram of a battery temperature sampling circuit of the battery management system with protection and equalization functions according to the present disclosure.

FIG. 5 is a schematic diagram of a PWM drive equalization circuit of the battery management system with protection and equalization functions according to the present disclosure.

FIG. 6 is a schematic diagram of a direct drive equalization circuit of the battery management system with protection and equalization functions according to the present disclosure.

In the figures: 100 and 100′, battery management system; 10, dedicated battery management IC; 11, battery protection module; 12, equalization module; 13, main control unit (MCU); 200, lithium battery pack; 21, charge-discharge circuit; 30, sampling circuits; 31, charge-discharge current sampling circuit; 32, battery temperature sampling circuit; 33, battery voltage sampling circuit; 40, execution circuits; 41, protection execution circuit; 411, charge-discharge control switch; 42, equalization execution circuit; 421, equalization MOS array; 422, equalization transformer; 424, isolation transformer; 423, magnetic core.

### DETAILED DESCRIPTION

Technical solutions in the embodiments of the present disclosure will be clearly and completely described below with reference to the accompanying drawings in the embodiments of the present disclosure. Obviously, the described embodiments are only a part of the embodiments of the present disclosure, rather than all the embodiments. Based on the embodiments in the present disclosure, all other embodiments obtained by those skilled in the art without paying any creative efforts belong to the scope of protection of the present disclosure.

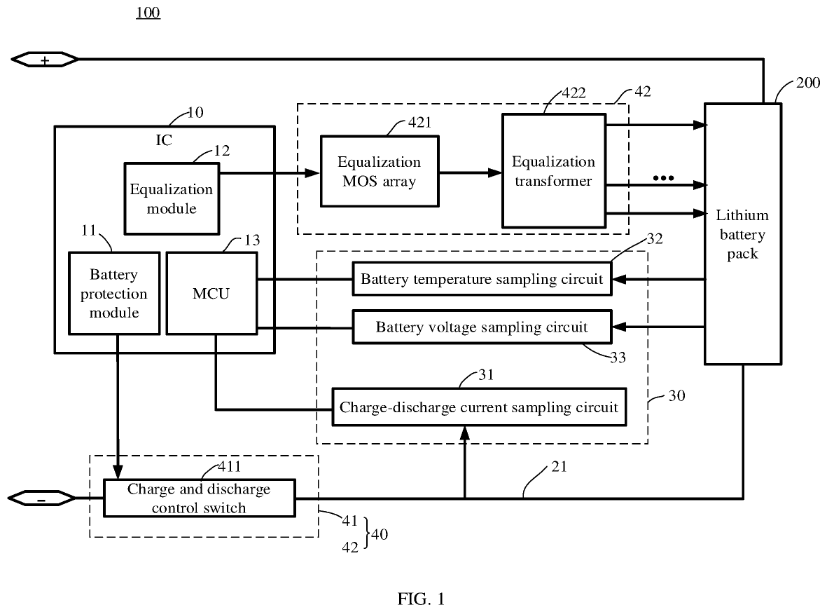

As illustrated in FIG. 1, the present disclosure provides a battery management system 100 with protection and equalization functions. The battery management system 100 includes a dedicated battery management IC 10, a plurality of sampling circuits 30 and a plurality of execution circuits 40. The dedicated battery management IC 10 is integrated with a battery protection module 11 and an equalization module 12. The sampling circuits 30 and the execution circuits 40 are coupled between the dedicated battery management IC 10 and a lithium battery pack 200, respectively.

The sampling circuits 30 collect parameters such as battery temperature, voltage, and charge-discharge current of the lithium battery pack 200, and input the parameters into the dedicated battery management IC 10 for analysis and processing. Specifically, the lithium battery pack 200 is a combination of a plurality of battery cells (not shown). The sampling circuits 30 include a charge-discharge current sampling circuit 31, a battery temperature sampling circuit 32, and a battery voltage sampling circuit 33. The battery temperature sampling circuit 32 is configured to collect the battery temperature of the lithium battery pack 200. The battery voltage sampling circuit 33 is configured to collect the voltages of each battery cell of the lithium battery pack 200. The charge-discharge current sampling circuit 31 is configured to collect charge-discharge current of the lithium battery pack 200.

In this embodiment, the dedicated battery management IC 10 is configured to analyze and process the parameters collected by the sampling circuits 30, and output control signals to the execution circuits 40 according to a result of the analysis and processing of the parameters, to control the execution circuits 40 to perform battery protection function and voltage equalization function of the lithium battery pack 200. That is, the execution circuits 40 receive the control signals output by the dedicated battery management IC 10, and protect the lithium battery pack 200 during charging and discharging, and equalize the voltages of the battery cells of the lithium battery pack 200.

In this embodiment, the execution circuits 40 include a protection execution circuit 41 coupled to the battery protection module 11 and an equalization execution circuit 42 coupled to the equalization module 12. The control signals comprise a protection signal and an equalization signal. The battery protection module 11 is configured to output the protection signal to the protection execution circuit 41 to control the protection execution circuit 41 to perform the battery protection function of the lithium battery pack 200. The equalization module 12 is configured to output the equalization signal to the equalization execution circuit 42 to control the equalization execution circuit 42 to perform the voltage equalization function of the lithium battery pack 200.

Specifically, as shown in FIG. 1, in this embodiment, the protection execution circuit 41 includes a charge-discharge control switch 411 coupled in series in a charge-discharge circuit 21 of the lithium battery pack 200. The battery protection module 11 outputs the protection signal to the charge-discharge control switch 411 to turned on or turned off the charge-discharge control switch 411, so as to conduct or disconnect the charge-discharge circuit 21, thereby provide protection for the lithium battery pack 200 during charging and discharging.

The equalization execution circuit 42 includes an equalization MOS array 421 and an equalization transformer 422, where the equalization MOS array 421 is coupled between the equalization module 12 and the equalization transformer 422, and the equalization transformer 422 is configured to be coupled to the lithium battery pack 200. In this embodiment, the equalization module 12 outputs the equalization signal to the equalization MOS array 421 to control an on-off state of the equalization MOS array 421, so as to equalize the voltages of the battery cells in the lithium battery pack 200.

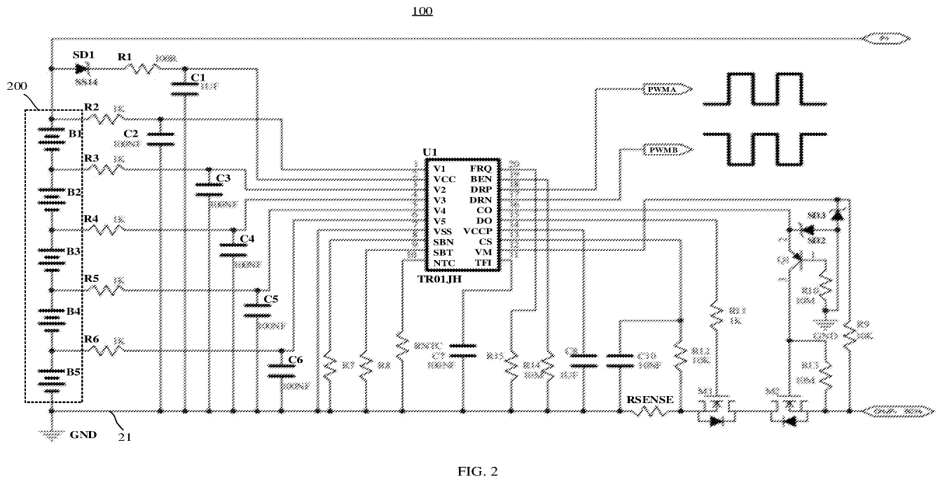

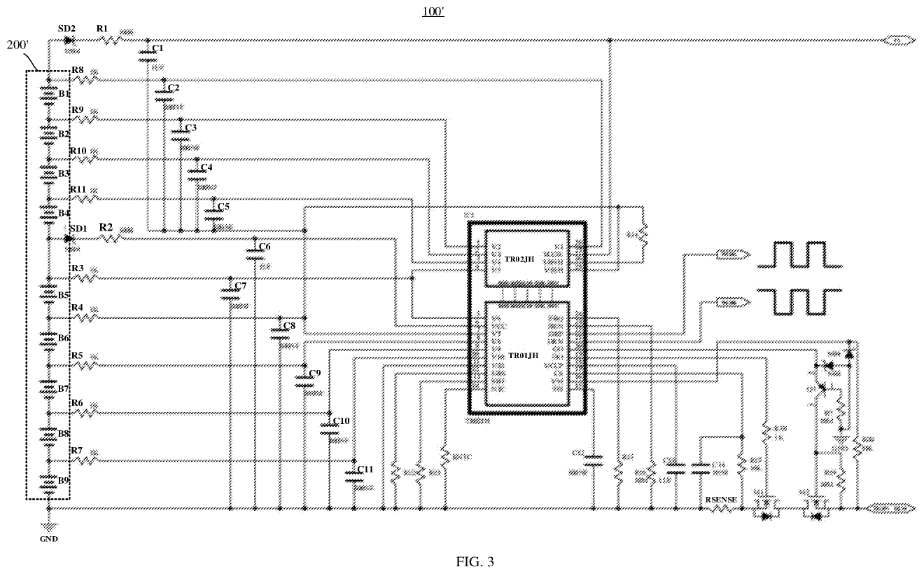

FIG. 2 is a working schematic diagram of the battery management system 100 of the present disclosure. As shown in FIG. 2, UI corresponds to the dedicated battery management IC 10 of the present disclosure. In one embodiment, UI can be a chip with a model of TR01JH. Each IC can provide protection and equalization for a battery pack with 5 battery cells or less. When there are more than 5 battery cells, multiple ICs can be cascaded, and each cascaded IC can provide battery protection function and voltage equalization function for 4 battery cells. The working schematic diagram of cascade please refer to FIG. 3. Pin definitions of TR01JH chip are shown in Table 1:

TABLE 1

| PIN | PIN | |
|---|---|---|
| Number | Definition | Function introduction |
| 1 | V1 | Voltage detection pin for the first battery cell |
| 2 | VCC | Input pin of chip's operating power supply |
| 3 | V2 | Voltage detection pin for the second battery cell |
| 4 | V3 | Voltage detection pin for the third battery cell |
| 5 | V4 | Voltage detection pin for the fourth battery cell |
| 6 | V5 | Voltage detection pin for the fifth battery cell |
| 7 | VSS | Power ground pin |
| 8 | SBN | Select the number of battery cells to be coupled in |
| | | series, up to 5 cells |
| 9 | SBT | Select battery cell equalization shutdown event, |
| | | 0.5-8 hours, four stages optional |
| 10 | NTC | Access pin for negative temperature coefficient |
| | | resistor. Resistance value is 10K, B value is 3435 |
| 11 | TFI | When adjusting the capacitance 0.1 μF in over- |
| | | current protection time, the over-current delay is 1 s |
| 12 | VM | Load state sensing pin in abnormal state |
| 13 | CS | charge-discharge current detection pin |
| 14 | VCCP | Balanced drive current power supply |
| 15 | DO | Discharge MOS control pin |
| 16 | CO | Charge MOS control pin |
| 17 | DRN | Balanced PWM output B phase |
| 18 | DRP | Balanced PWM output A phase |
| 19 | BEN | Balance function enable terminal |
| 20 | FRQ | Balance reference frequency selection pin. 20-200K |

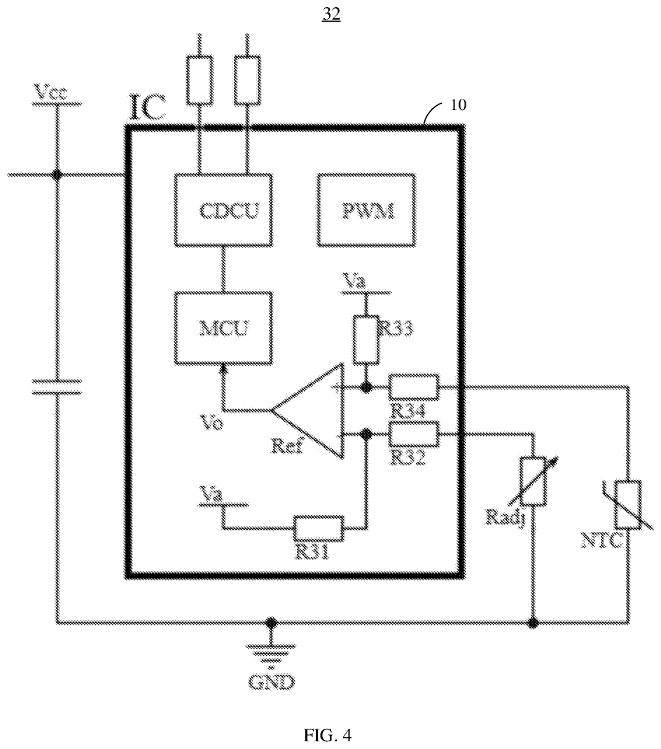

FIG. 4 is a schematic diagram of the battery temperature sampling circuit 32 of the present disclosure. As shown in FIG. 4, the battery temperature sampling circuit 32 includes a thermistor NTC closely attached to a surface of the lithium battery pack 200 for collecting the battery temperature of the lithium battery pack 200.

Specifically, the dedicated battery management IC 10 further includes a comparator Ref. The battery temperature sampling circuit 32 further includes an external adjustable resistor Radj. One terminal of the thermistor NTC is coupled to the interior of the dedicated battery management IC 10 and then coupled, through a resistor R34, to a non-inverting input terminal + of the comparator Ref inside the dedicated battery management IC 10, where the non-inverting input terminal + is pulled up to a reference standard voltage Va through a resistor R33. The other terminal of the thermistor NTC is coupled to the interior of the dedicated battery management IC 10 through the external adjustable resistor Radj, and then coupled, through a resistor R32, to an inverting input terminal − of the comparator Ref inside the dedicated battery management IC 10, where the inverting input terminal − is pulled up to the reference standard voltage Va through a resistor R31. A connection node between the thermistor NTC and the external adjustable resistor Radj is grounded.

A resistance value of the thermistor NTC changes with the change of the battery temperature of the lithium battery pack 200, making the voltage at the non-inverting input terminal + change. The comparator Ref outputs an output signal V0 according to the voltages at the non-inverting input terminal + and the inverting input terminal −. Specifically, when the battery temperature of the lithium battery pack 200 is low, the resistance value of the thermistor NTC is large (such as 50kΩ or 100kΩ), the voltage input to the non-inverting input terminal + of the comparator Ref is greater than the voltage input to the inverting input terminal −, so that the output signal V0 of the comparator Ref is a high-level signal. When the battery temperature of the lithium battery pack 200 rises, the thermistor NTC is heated and its resistance value decreases, which reduces the voltage input to the non-inverting input terminal + of the comparator Ref. When the temperature of the lithium battery pack 200 rises to a threshold value, the voltage input to the non-inverting input terminal + of the comparator Ref is less than the voltage input to the inverting input terminal −, so that the output signal V0 of the comparator Ref is a low-level signal.

The battery protection module 11 (as shown in FIG. 1) includes a charge-discharge control unit CDCU (as shown in FIG. 4) coupled to the charge-discharge control switch 411. The dedicated battery management IC 10 further includes a main control unit MCU coupled to the charge-discharge control unit CDCU and an output terminal of the comparator Ref, respectively. In this embodiment, the main control unit MCU determines whether the battery temperature of the lithium battery pack 200 is too high according to the output signal V0 output by the comparator Ref, and then drives, according to a determination result, the charge-discharge control unit CDCU to output the protection signal to turn on or turn off the charge-discharge control switch 411, so as to conduct or disconnect the charge-discharge circuit 21 of the lithium battery pack 200.

The structures of the battery voltage sampling circuit 33, the charge-discharge current sampling circuit 31, and the protection execution circuit 41 of the present disclosure please refer to FIG. 2. In this embodiment, as shown in FIG. 2, the lithium battery pack 200 is a battery pack including five battery cells B1, B2, B3, B4 and B5 coupled in series, where a negative electrode of the battery cell B5 is grounded.

As shown in FIG. 2, the battery voltage sampling circuit 33 includes voltage sampling resistors R2, R3, R4, R5, R6 corresponding to the battery cells B1, B2, B3, B4 and B5 one by one. The voltage sampling resistors R2, R3, R4, R5, R6 also correspond to the voltage detection pins V1, V2, V3, V4, V5 of the dedicated battery management IC 10 one by one. Each of the voltage sampling resistors (R2, R3, R4, R5, R6) is coupled between a positive electrode of a corresponding battery cell (B1, B2, B3, B4 and B5) and a corresponding voltage detection pin (V1, V2, V3, V4, V5). That is, the voltage sampling resistors R2 is coupled between a positive electrode of the battery cell B1 and a voltage detection pin V1 of the dedicated battery management IC 10, the voltage sampling resistor R3 is coupled between a positive electrode of the battery cell B2 and the voltage detection pin V2 of the dedicated battery management IC 10, the voltage sampling resistor R4 is coupled between a positive electrode of the battery cell B3 and the voltage detection pin V3 of the dedicated battery management IC 10, the voltage sampling resistor R5 is coupled between a positive electrode of the battery cell B4 and the voltage detection pin V4 of the dedicated battery management IC 10, and the voltage sampling resistor R6 is coupled between a positive electrode of the battery cell B5 and the voltage detection pin V5 of the dedicated battery management IC 10. The dedicated battery management IC 10 detects the voltage of the positive electrode of each battery cell (B1, B2, B3, B4, B5) through a corresponding voltage detection pin (V1, V2, V3, V4, V5) and a corresponding voltage sampling resistor (R2, R3, R4, R5, R6).

The battery voltage sampling circuit 33 further includes a plurality of capacitors C2, C3, C4, C5, C6 corresponding to the voltage detection pins V1, V2, V3, V4, V5 of the dedicated battery management IC 10 one by one. The capacitors C2, C3, C4, C5, C6 also correspond to the voltage sampling resistors R2, R3, R4, R5, R6 one by one. Each of the capacitors (C2, C3, C4, C5, C6) is coupled between a corresponding voltage detection pin (V1, V2, V3, V4, V5) and a power ground pin VSS of the dedicated battery management IC 10. That is, the capacitor C2 is coupled between the voltage detection pin V1 and the power ground pin VSS of the dedicated battery management IC 10, the capacitor C3 is coupled between the voltage detection pin V2 and the power ground pin VSS, the capacitor C4 is coupled between the voltage detection pin V3 and the power ground pin VSS, the capacitor C5 is coupled between the voltage detection pin V4 and the power ground pin VSS, and the capacitor C6 is coupled between the voltage detection pin V5 and the power ground pin VSS. Each of the voltage sampling resistors (R2, R3, R4, R5, R6) form a RC filter loop with its corresponding capacitor (C2, C3, C4, C5, C6) to filter high-frequency noise on a corresponding battery sampling circuit.

The charge-discharge current sampling circuit 31 includes a current sampling resistor RSENSE coupled in series in the charge-discharge circuit 21 of the lithium battery pack 200, and coupled to the charge-discharge current detection pin CS of the dedicated battery management IC 10. In this embodiment, the current sampling resistor RSENSE includes a first terminal coupled to the charge-discharge current detection pin CS through a resistor R12, and a second terminal coupled to the negative electrode of the battery cell B5 and grounded. In use, current flows through the current sampling resistor RSENSE, and the dedicated battery management IC 10 can detect, through the charge-discharge current detection pin CS and the resistor R12, the voltage at the first terminal of the current sampling resistor RSENSE, and determine a charge-discharge state and a charge-discharge current of the lithium battery pack 200 according to the voltage detected through the charge-discharge current detection pin CS. In this embodiment, the polarity of the voltage at the charge-discharge current detection pin CS represents a charge-discharge state of the lithium battery pack 200. When the voltage value of the pin CS is greater than 0V, it indicates that the lithium battery pack 200 is in a discharge state. When the voltage value of the pin CS is less than 0V, it indicates that the lithium battery pack 200 is in a charging state. When the lithium battery pack 200 is charged or and discharges, the current value I in the charge-discharge circuit 21 can be obtained according to the following formula: I=Vcs/Rs, where Vcs represents the voltage at the pin CS, and Rs represents the resistance value of the current sampling resistor RSENSE. The dedicated battery management IC 10 compares the current value I with an over-current protection current threshold, and output the protection control signal to the execution circuit 41 when the dedicated battery management IC 10 determines that the current value I is greater than the threshold current, so that the protection execution circuit 41 stops the charging and discharging of the lithium battery pack 200 based on the protection control signal.

In this embodiment, as shown in FIG.2, the charge-discharge control switch 411 includes a first charge-discharge control MOS transistor M1 and a second charge-discharge control MOS transistor M2 coupled in series in the charge-discharge circuit 21. A method of the battery protection is that: when the battery temperature detected by the battery temperature sampling circuit 32 is too high, the main control unit MCU inside the dedicated battery management IC 10 outputs a drive signal to the charge-discharge control unit CDCU, to drive the charge-discharge control unit CDCU to output the protection control signal through the pin DO or CO to the gate of the charge-discharge control MOS transistor M1 or M2 according to the polarity of the voltage at the pin CS, to turn off the charge-discharge control MOS transistor M1 or M2, so as to disconnect the charge-discharge circuit 21, thereby stopping the charging or discharging of the lithium battery pack 200. The dedicated battery management IC 10 detects various voltage values through its voltage detection pins V1, V2, V3, V4, V5 and the current detection pin CS, respectively, and compares the detected voltage values with corresponding set threshold values. If one of the detected voltage values exceeds the corresponding threshold value set by the system, the charge-discharge control unit CDCU controls, through the DO or CO pin, the charge-discharge control MOS transistor M1 or M2 to disconnect the charge-discharge circuit 21, so as to stop the charging and discharging of the lithium battery pack 200.

In this embodiment, the equalization module 12 (as shown in FIG. 1) includes a PWM generator PWM (as shown in FIG. 4) coupled to the pins DRN and DRP of the dedicated battery management IC 10. In this embodiment, the PWM generator PWM can be an internal totem pole that is driven to generate PWM square wave signal and outputs the PWM square wave signal to the equalization MOS array 421 through the pins DRN and DRP, where the PWM square wave signal is the equalization signal.

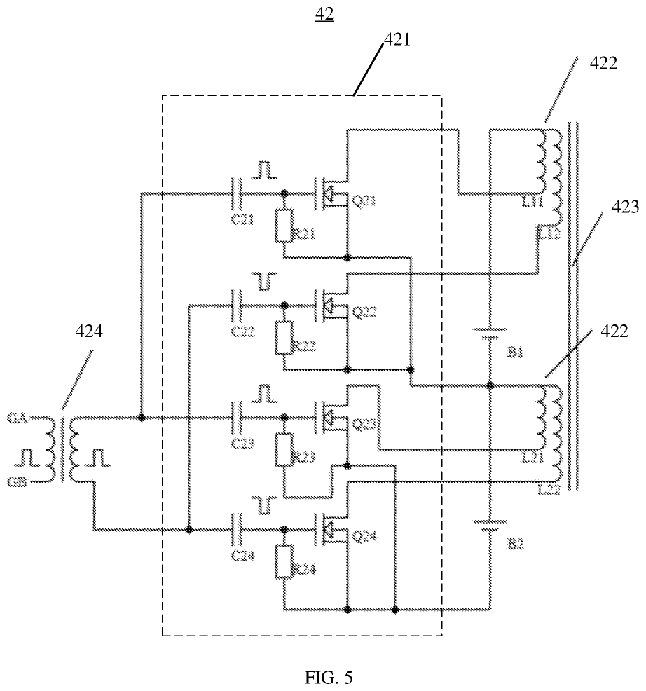

FIG. 5 is a schematic diagram of a PWM drive equalization circuit (corresponding to the equalization execution circuit 42) of the present disclosure. As shown in FIG. 5, the PWM drive equalization circuit includes the equalization MOS array 421, the equalization transformer 422, a magnetic core 423, and an isolation transformer 424. A left side of the isolation transformer 424 is a primary end with two terminals GA and GB coupled to the pins DRN and DRP of the dedicated battery management IC 10 to receive phases A and B of the PWM square wave signal. Take the equalization execution circuit of the battery cells B1 and B2 as an example, the equalization MOS array 421 includes MOS transistors Q21, Q22, Q23, and Q24. The equalization execution circuit further includes four capacitors C21, C22, C23, and C24. The capacitor C21 is coupled between an upper part of the homonymous end of the isolation transformer 424 and a gate of the MOS transistors Q21, the capacitor C23 is coupled between the upper part of the homonymous end of the isolation transformer 424 and a gate of the MOS transistors Q23, the capacitor C22 is coupled between a lower part of the homonymous end of the isolation transformer 424 and a gate of the MOS transistors Q22, and the capacitor C24 is coupled between the lower part of the homonymous end of the isolation transformer 424 and a gate of the MOS transistors Q24.

When the PWM square wave signal output to the terminal GA is a high level signal, while the PWM square wave output to the terminal GB is a low level signal, the current flows from GA to GB through the primary end of the isolation transformer 424, and drives a homonymous end of the isolation transformer 424 to generate induced current. An upper part of the homonymous end is in a high level state relative to the lower part. Capacitors C21 and C23 are coupled to a high level voltage, and the gates of MOS transistors Q21 and Q23 are in a high level state, so that Q21 and Q23 are turned on. Capacitors C22 and C24 are coupled to a low level voltage, and the gates of MOS transistors Q22 and Q24 are in a low level state, so that Q22 and Q24 are turned off. In this way, current flows from the positive electrode of the battery cell B1 to the winding L11, and then back to the negative electrode of the battery cell B1 through Q21. On the other path, a loop from the positive electrode of B2 to the winding L21, and then back to the negative electrode of the battery cell B2 through the Q23, is turned on. If the difference of induced voltage between two ends of L21 is greater than the voltage of the battery cell B2, the battery cell B2 is charged; otherwise, the difference of the induced voltage between two ends of the winding L11 is greater than the voltage of the battery cell Bl, the battery cell B2 discharges to the loop, and the battery cell B1 is charged.

When the PWM square wave signal output to the terminal GA is a low level signal, while the PWM square wave output to the terminal GB is a high level signal, the current flows from GB to GA through the primary end of the isolation transformer 424, and drives the homonymous end of the isolation transformer 424 to generate induced current. The upper part of the homonymous end is in a low level state relative to the lower part. The capacitors C21 and C23 are coupled to a low level voltage, and the gates of MOS transistors Q21 and Q23 are in a low level state, so that Q21 and Q23 are turned off. The capacitors C22 and C24 are coupled to a high level voltage, and the gates of the MOS transistors Q22 and Q24 are in a high level state, so that Q22 and Q24 are turned on. In this way, the current flows from the positive electrode of battery cell B1 to the winding L12, and then back to the negative electrode of battery cell B1 through Q22. On the other path, a loop from the positive electrode of B2 to the winding L22, and then back to the negative electrode of battery cell B2 through Q24, is turned on. If the difference of the induced voltage between two ends of L22 is greater than the voltage of the battery cell B2, the battery cell B2 is charged; otherwise, the difference of the induced voltage between two ends of the winding L12 is greater than the voltage of the battery cell Bl, the battery cell B2 discharges to the loop, and the battery cell B1 is charged.

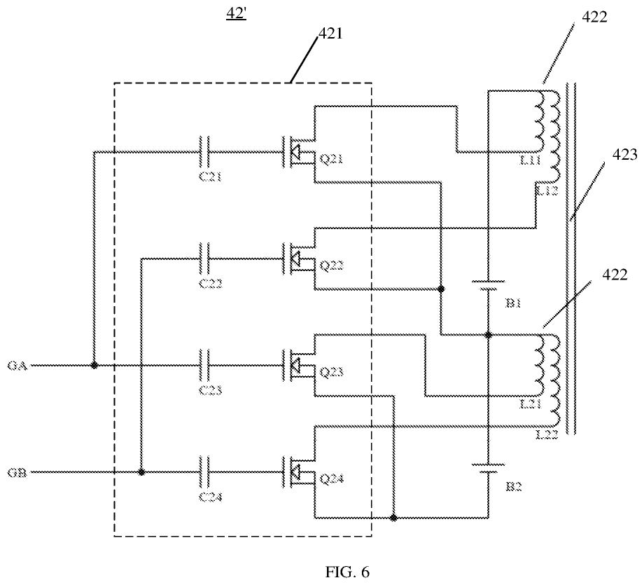

FIG. 6 is a schematic diagram of a direct drive equalization circuit (corresponding to the equalization execution circuit 42) of the present disclosure. Compared with the PWM drive equalization circuit as shown in FIG. 5, in the direct drive equalization circuit as shown in FIG. 6, the isolation transformer 424 is removed. The direct drive equalization circuit includes the two terminals GA and GB coupled to the pins DRN and DRP of the dedicated battery management IC 10, both of the capacitors C21 and C23 are coupled to the terminal GA, and then coupled to the MOS transistors Q21 and Q23 respectively. Both of the capacitors C22 and C24 are coupled to the terminal GB, and then coupled to the MOS transistors Q22 and Q24 respectively. When PWMA outputs a high level signal relative to PWMB, Q21 and Q23 are turned on, and a loop from the positive electrode of the battery cell B1 to the winding L11, and then back to the negative electrode of the battery cell B1 through Q21 is formed. On the other path, a loop from the positive electrode of battery cell B2 to the winding L21, and then back to the negative electrode of battery cell B2 through Q23 is formed. There are induced voltage at both ends of the winding L11 and L21. If the battery voltage of a battery cell is lower than the difference of the induced voltage between two ends of a corresponding winding, the battery cell is charged, otherwise, the battery cell discharges to the loop.

When PWMA outputs a low level signal relative to PWMB, Q22 and Q24 are turned on, and a loop from the positive electrode of the battery cell B1 to the winding L12, and then back to the negative electrode of the battery cell B1 through Q22 is formed. On the other path, a loop from the positive electrode of battery cell B2 to the winding L22, and then back to the negative electrode of the battery cell B2 through Q24 is formed. There are induced voltages at both ends of the winding L12 and L22. If the battery voltage of a battery cell is lower than the difference of the induced voltage between two ends of a corresponding winding, the battery is charged, otherwise, the battery discharges to the loop.

The above are only the preferred embodiments of the present disclosure. It should be pointed out that for those of ordinary skill in the art, without departing from the inventive concept of the present disclosure, certain modifications and improvements can be made, which belong to the scope of protection of the present disclosure.

What is claimed is:

1. A battery management system with protection and equalization functions, comprising:
a dedicated battery management IC integrating a battery protection module and an equalization module;
a plurality of sampling circuits coupled between the dedicated battery management IC and a lithium battery pack, wherein the sampling circuits are configured to collect parameters of the lithium battery pack and input the parameters into the dedicated battery management IC for analysis and processing; wherein the parameters comprise voltage, charge-discharge current and battery temperature of the lithium battery pack; wherein the dedicated battery management IC is configured to analyze and process the parameters collected by the sampling circuits, and output corresponding control signals according to a result of the analysis and processing of the parameters; wherein the control signals comprise a protection signal and an equalization signal; and
a plurality of execution circuits coupled between the dedicated battery management IC and the lithium battery pack, wherein the execution circuits are configured to receive the control signals output by the dedicated battery management IC, and perform battery protection function and voltage equalization function of the lithium battery pack; wherein the execution circuits comprise:
a protection execution circuit coupled to the battery protection module, wherein the battery protection module is configured to output the protection signal to the protection execution circuit to control the protection execution circuit to perform the battery protection function of the lithium battery pack; and
an equalization execution circuit coupled to the equalization module, wherein the equalization module is configured to output the equalization signal to the equalization execution circuit to control the equalization execution circuit to perform the voltage equalization function of the lithium battery pack.

2. The battery management system with protection and equalization functions of claim 1, wherein the protection execution circuit comprises a charge-discharge control switch coupled in series in a charge-discharge circuit of the lithium battery pack; wherein the battery protection module outputs the protection signal to the charge-discharge control switch to turned on or turned off the charge-discharge control switch, so as to conduct or disconnect the charge-discharge circuit, thereby provide protection for the lithium battery pack during charging and discharging.

3. The battery management system with protection and equalization functions of claim 2, wherein the sampling circuits comprise a battery temperature sampling circuit, wherein the battery temperature sampling circuit comprises a thermistor closely attached to a surface of the lithium battery pack for collecting the battery temperature of the lithium battery pack; wherein the resistance value of the thermistor NTC is changes with the change of the battery temperature of the lithium battery pack.

4. The battery management system with protection and equalization functions of claim 3, wherein the dedicated battery management IC further comprises a comparator; the battery temperature sampling circuit further comprises an adjustable resistor;
wherein one terminal of the thermistor is coupled to a non-inverting input terminal of the comparator, and the other end of the thermistor is coupled to an inverting input terminal of the comparator through the adjustable resistor; wherein the non-inverting input terminal is pulled up to a reference standard voltage through a first resistor, the inverting input terminal is pulled up to the reference standard voltage through a second resistor, and a connection node between the thermistor and the adjustable resistor is grounded; the comparator outputs an output signal according to the voltages at the non-inverting input terminal and the inverting input terminal.

5. The battery management system with protection and equalization functions of claim 4, wherein the battery protection module comprises a charge-discharge control unit coupled to the charge-discharge control switch;
the dedicated battery management IC further comprises a main control unit coupled to the charge-discharge control unit and an output terminal of the comparator, respectively, wherein the main control unit is configured to determine whether the battery temperature of the lithium battery pack is too high according to the output signal output by the comparator, and then drive, according to a determination result, the charge-discharge control unit to output the protection signal to turn on or turn off the charge-discharge control switch, so as to conduct or disconnect the charge-discharge circuit of the lithium battery pack.

6. The battery management system with protection and equalization functions of claim 1, wherein the lithium battery pack comprises a plurality of battery cells; the sampling circuits comprise a battery voltage sampling circuit configured to collect the voltages of each battery cell of the lithium battery pack;
wherein the battery voltage sampling circuit comprises a plurality of voltage sampling resistors corresponding to the battery cells of the lithium battery pack one by one, wherein the voltage sampling resistors also correspond to a plurality of voltage detection pins of the dedicated battery management IC one by one; wherein each of the voltage sampling resistors is coupled between a positive electrode of a corresponding battery cell and a corresponding voltage detection pin;
wherein the dedicated battery management IC detects the voltage of the positive electrode of each battery cell through a corresponding voltage detection pin and a corresponding voltage sampling resistor.

7. The battery management system with protection and equalization functions of claim 6, wherein the battery voltage sampling circuit further comprises a plurality of capacitors corresponding to the voltage detection pins of the dedicated battery management IC one by one, wherein the capacitors also correspond to the voltage sampling resistors one by one;
wherein each of the capacitors is coupled between a corresponding voltage detection pin and a power ground pin of the dedicated battery management IC; each of the voltage sampling resistors form a RC filter loop with its corresponding capacitor to filter high-frequency noise on a corresponding battery sampling circuit.

8. The battery management system with protection and equalization functions of claim 1, wherein the lithium battery pack comprises a plurality of battery cells coupled in series, wherein a negative electrode of one of the battery cells is grounded;
the sampling circuits comprise a charge-discharge current sampling circuit configured to collect charge-discharge current of the lithium battery pack, wherein the charge-discharge current sampling circuit comprises a current sampling resistor coupled in series in the charge-discharge circuit of the lithium battery pack, and coupled to a charge-discharge current detection pin of the dedicated battery management IC.

9. The battery management system with protection and equalization functions of claim 8, wherein the current sampling resistor comprises a first terminal coupled to the charge-discharge current detection pin, and a second terminal coupled to the negative electrode of the one of the battery cell and grounded;
the dedicated battery management IC detects, through the charge-discharge current detection pin, the voltage at the first terminal of the current sampling resistor, and determines a charge-discharge state and a charge-discharge current of the lithium battery pack according to the voltage detected through the charge-discharge current detection pin.

10. The battery management system with protection and equalization functions of claim 2, wherein the charge-discharge control switch comprises a first charge-discharge control MOS transistor and a second charge-discharge control MOS transistor coupled in series in the charge-discharge circuit.

11. The battery management system with protection and equalization functions of claim 1, wherein the lithium battery pack comprises a plurality of battery cells, the equalization execution circuit comprises an equalization MOS array and an equalization transformer, wherein the equalization MOS array is coupled between the dedicated equalization module and the equalization transformer, the equalization transformer is configured to be coupled to the lithium battery pack;
the equalization module outputs the equalization signal to the equalization MOS array to control an on-off state of the equalization MOS array, so as to equalize voltages of the battery cells in the lithium battery pack.

12. The battery management system with protection and equalization functions of claim 11, wherein the equalization module comprises a PWM generator that is driven to generate PWM square wave signal and outputs the PWM square wave signal to the MOS array, wherein the PWM square wave signal is the equalization signal.

13. The battery management system with protection and equalization functions of claim 7, wherein the battery management system comprises more than one dedicated battery management ICs that are cascaded, wherein each cascaded dedicated battery management IC is configured to provide protection and equalization for a preset number of battery cells.
